(19) United States
(12) Patent Application Publication
(10) Pub. No.: US 2008/0251282 A1
(43) Pub. Date: Oct. 16, 2008

(54) HIGHLY THERMALLY CONDUCTIVE CIRCUIT SUBSTRATE

(75) Inventors: Hsu-Tan HUANG, Taipei County (TW); Chung-Lin CHOU, Taipei County (TW)

Correspondence Address: BROWDY AND NEIMARK, P.L.L.C.;624 NINTH STREET, NW, SUITE 300, WASHINGTON, DC, 20001-5303, US

(73) Assignee: Cosmos Vacuum Technology Corporation, Taipei County (TW)

(21) Appl. No.: 11/775,274

(22) Filed: Jul. 10, 2007

(30) Foreign Application Priority Data
Apr. 10, 2007 (TW) 96112544

(51) Int. Cl. H05K 1/03

(52) U.S. Cl. 174/255

(57) ABSTRACT

A highly thermally conductive circuit substrate includes a metallic substrate, an insulated layer, a first medium layer, and an electrically conductive layer. The insulated layer is formed on a surface of said metallic substrate. The first medium layer is formed on a surface of said insulated layer. The electrically conductive layer is formed on a surface of said first medium layer.

### BACKGROUND OF THE INVENTION

1. Field of the Invention

The present invention relates generally to circuit substrates and more particularly, to a highly thermally conductive circuit substrate.

2. Description of the Related Art

Referring to FIGS. 1 and 2, Taiwan Patent Pre-Grant Pub. No. 200520670 disclosed an integrated thermally conductive substrate and a method of preparing the same. The method includes the steps of preparing a metallic substrate 1, producing an insulated layer 2 made of aluminum trioxide on the metallic substrate 1 by means of micro arc oxidation (MAO) anodizing for thermal conduction, and disposing a metallic film 3, which is made of copper and has a predetermined design, on the insulated layer with a vacuum-coated film to define a plurality of metal wires and to produce an integrated thermally conductive substrate 4. This invention is for the purpose of integration, thermal conduction, and circuit layout in such a way that the metallic substrate 1 is provided for thermal conductivity, the insulated layer 2 is provided for electrical insulation, and the metal film 3 is provided for circuit layout.

However, the insulated layer 2 is much different from the metal film 3 in physical property, like coefficient of expansion, and both of the insulated layer 2 and the metallic film 3 are applicable to the processing of high temperature first and then low temperature, so that the integrated thermally conductive substrate is subject to having raised surface resulted from stress. Especially for the large substrate, the raised surface is more obvious. The substrate is also subject to peeling, i.e. the peel strength is low.

In addition, the electrical conductivity of circuit will be preferable if the thickness of the electrically conductive layer is at least 13 μm. For the electrical conductivity of circuit having higher power, it will be preferable if the thickness of the electrically conductive layer is at least 20 μm. However, the thickness of the above-mentioned metallic film 3 made by the vacuum coating is 9 μm at most and if it is more than 9 μm, the metal film 3 may peel off, such that the above-mentioned thermally conductive substrate is defective in that the metallic film 3 is too thin to have preferable electrical conductivity. Furthermore, the vacuum coating by which the electrically conductive film is made is slower in formation of the film to defectively take more working hours. In other words, the vacuum coating that the electrically conductive film is made has drawbacks of imperfect electric conductivity and costing more working hours.

Because the insulated layer 2 made of aluminum trioxide of the above-mentioned substrate is made by MAO anodizing and the crystal structure of aluminum trioxide is superimposed other than regularly columnar, the thermal conductivity of the substrate is imperfect for farther improvement.

### SUMMARY OF THE INVENTION

The primary objective of the present invention is to provide a highly thermally conductive circuit substrate, which takes a first medium layer as a buffer interface for intensifying the structure thereof.

The secondary objective of the present invention is to provide a highly thermally conductive circuit substrate, which provides different types of the insulated layer to further increase the regularity of the crystal morphology, thus having better thermally conductive efficiency.

The foregoing objectives of the present invention are attained by the highly thermally conductive circuit substrate, which includes a metallic substrate, an insulated layer, a first medium layer, and an electrically conductive layer. The insulated layer is formed on a surface of said metallic substrate. The first medium layer is formed on a surface of said insulated layer. The electrically conductive layer is formed on a surface of said first medium layer.

In light of the above, the present invention taking the first medium layer as the buffer interface can overcome the overgreat difference of the physical property between the insulated and electrically conductive layers and enhance the adherence between the insulated and electrically conductive layers. Compared with the prior art, the present invention can intensify the structure between the insulated and electrically conductive layers to have highly intense structure therebetween.

### BRIEF DESCRIPTION OF THE DRAWINGS

FIG. 1 is a sectional view of Taiwan Patent Pre-Grant Pub. No. 200520670.

FIG. 2 is another sectional view of Taiwan Patent Pre-Grant Pub. No. 200520670.

FIG. 3 is a sectional view of a first preferred embodiment of the present invention.

FIG. 4 is an enlarged view of a part of the first preferred embodiment of the present invention.

FIG. 5 is a sectional view of a second preferred embodiment of the present invention.

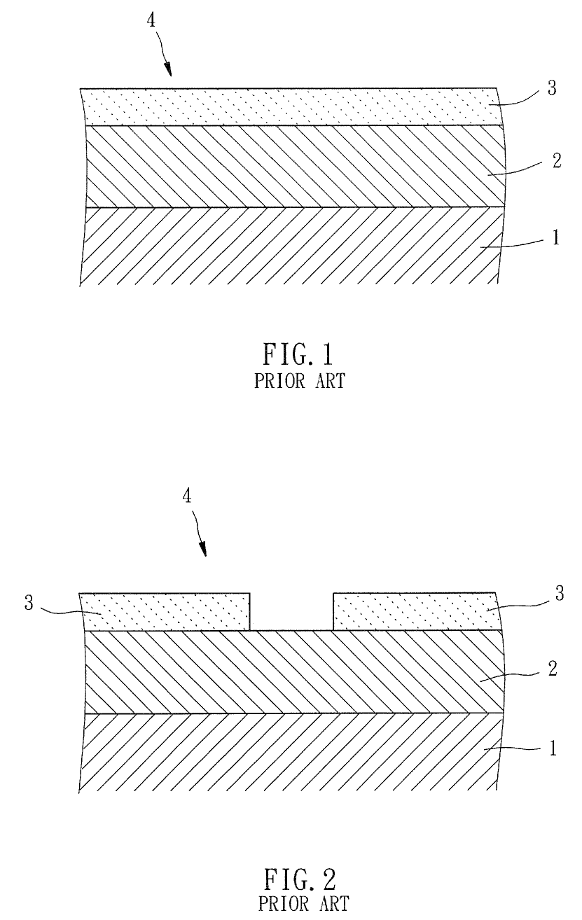

### DETAILED DESCRIPTION OF PREFERRED EMBODIMENTS

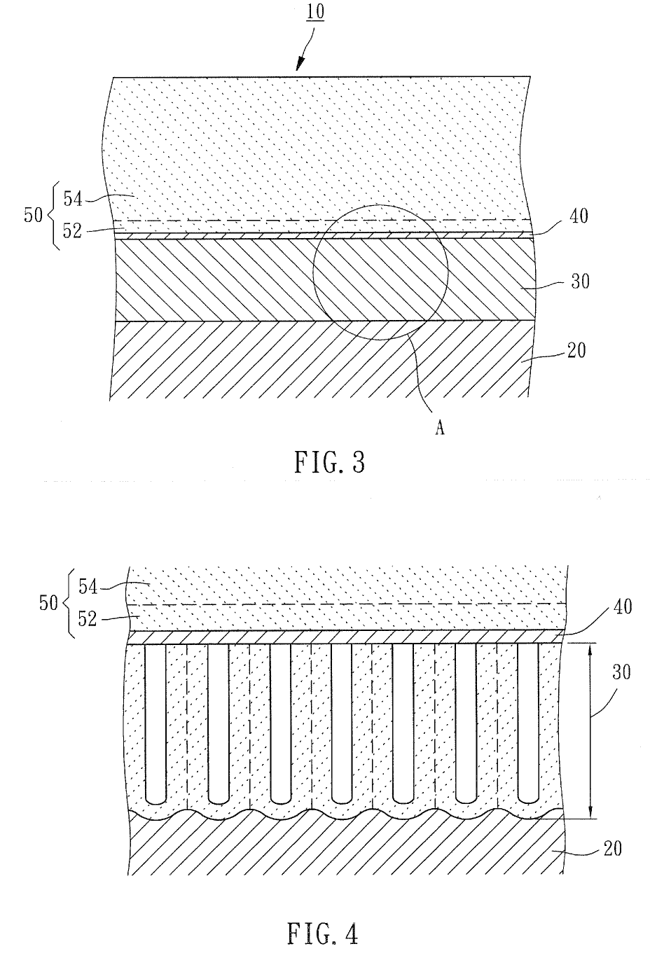

Referring to FIGS. 3 and 4, a highly thermally conductive circuit substrate 10, constructed according to a first preferred embodiment of the present invention, is composed of a metallic substrate 20, an insulated layer 30, a first medium layer 40, and an electrically conductive layer 50.

The metallic substrate 20 is made of a material selected from a group consisting of aluminum, magnesium, titanium, and an alloy of at least two of them. In this embodiment, the metallic substrate 20 is made of aluminum.

The insulated layer 30 is formed on a surface of the metallic substrate 20 by means of anodizing, such as conventional MAO anodizing and plasma electrolytic oxidation (PEO), and is made of oxide of the metal that the metallic substrate 20 is made. In this embodiment, the insulated layer 30 is made of aluminum trioxide. However, to enable preferable thermal conductivity of the insulated layer 20 of aluminum trioxide, the aluminum trioxide is formed by means of electrochemical colloid oxidation (ECCO) anodizing developed by the present inventor. The ECCO anodizing is characterized in that the working solution is oxalic acid, the predetermined working voltage is 260-400 volts, and the predetermined working current is 2-5 A/dm², enabling preferable regularity of the crystal morphology of the insulated layer 20 and preferable thermal conductivity.

The first medium layer 40 is formed on a surface of the insulated layer 30 by means of physical vapor deposition (PVD) or chemical vapor deposition (CVD) and is located between the insulated and electrically conductive layers 30 and 50. The first medium layer 40 is made of magnesium, aluminum, titanium, vanadium, chromium, nickel, zirconium, molybdenum, tungsten, or a compound of at least two of them. In this embodiment, the first medium layer is made of titanium oxide.

The electrically conductive layer 50 is formed on a surface of the first medium layer 40 by PVD, CVD, or electrochemical technology and is made of aluminum, cobalt, nickel, copper, zinc, argentums, tin, platinum, or gold. The electrically conductive layer 50 can form a circuit layout for electric conduction. The electrically conductive layer 50 can define an electrically conductive medium layer 52 and an electrically conductive main layer 54 according to different processing methods. The electrically conductive main layer 52 is formed on a surface of the first medium layer 40 by means of PVD and is made of copper, having a thickness smaller than 1 μm. The electrically conductive main layer 54 is formed on a surface of the electrically conductive medium layer 52 by means of electroplating and is made of cooper, having a thickness of 35 μm larger than 13 μm. It is to be noted that the primary reason of defining the electrically conductive medium layer 52 and the electrically conductive main layer 54 from the electrically conductive layer 50 lies in that the processing of PVD is slow, and thus the present invention produces an ultra-thin electrically conductive medium layer 52 (below 1 μm) to shorten the processing time. Further, the electroplating which processing rate is larger than that of the PVD can accelerate the production of the electrically conductive main layer 54 to increase the rate of the manufacturing process of the present invention. Meanwhile, it also thickens the electrically conductive main layer 54 to enhance the electric conductivity of the highly thermally conductive circuit substrate 10. If the electrically conductive medium layer 52 and the electrically conductive main layer 54 are made of the same metal, it will be difficult to distinguish their textural difference. On the contrary, if the electrically conductive medium layer 52 and the electrically conductive main layer 54 are made of different metals, it will be easy to distinguish their textural difference. In this embodiment, the electrically conductive medium layer 52 and the electrically conductive main layer 54 are made of the same metal (copper), and thus it is difficult to distinguish their textural difference.

In light of the above, the technical features of the present invention lie in that the first medium layer 40 is used for a buffer interface and has the physical property between those of the insulated and electrically conductive layers 30 and 50 to further shorten the difference of the physical property therebetween, thus overcoming the problem that the difference of physical property between the insulated and electrically conductive layers 30 and 50 is overgreat. In other words, on the one hand, the first medium layer 40 can prevent the highly thermally conductive circuit substrate 10 from raised surface; on the other hand, the first medium layer 40 can intensify the adherence between the insulated and electrically conductive layers 30 and 50 to have preferable peel strength. Compared with the prior art, the present invention intensifies the structure between the insulated and electrically conductive layers 30 and 50 to highly intense structure thereof.

In addition, the present invention defines an ultra-thin electrically conductive medium layer 52 and a relatively thick electrically conductive main layer 54 on the electrically conductive layer 50 by means of different processing methods, i.e. the ultra-thin electrically conductive medium layer 52 is formed by the slower PVD. The purpose of the electrically medium layer 34 is to form the metallic electrode in advance for the next electroplating and form the electrically conductive main layer 54 on the electrically conductive medium layer 34, and then to form the relatively thick electrically conductive main layer 54 by the faster electroplating. Therefore, the present invention can be made in mass production.

Moreover, an oxide layer is formed by the conventional MAO to have the superimposed crystal morphology, and the present invention employs the ECCO anodizing to form the insulated layer 30 having porous cylindrical crystal morphology other than the superimposed one to enhance the thermally conductive efficiency. After testing the highly thermally conductive circuit substrate 50, the coefficient of thermal conductivity reaches 100 W/m·K and above.

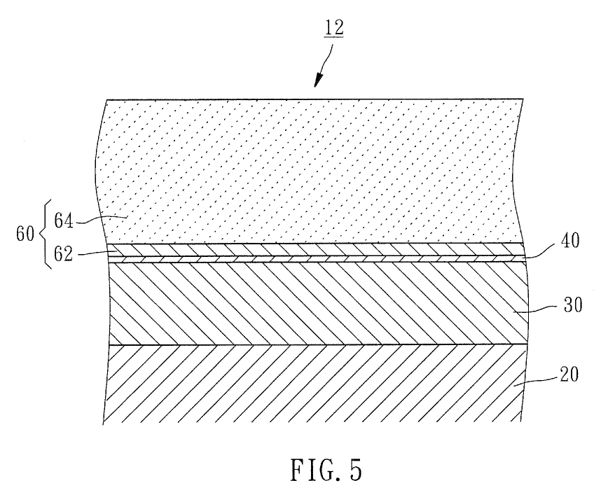

Referring to FIG. 5, a highly thermally conductive circuit substrate 12, constructed according to a second preferred embodiment of the present invention, is similar to the first embodiment but different in that the electrically conductive medium layer 62 and the electrically conductive main layer 64 of the electrically conductive layer 60 are made of different metals; namely, the electrically conductive medium layer 62 is still made of cooper and the electrically conductive main layer 64 is made of argentum. In texture, it is easy to distinguish the electrically conductive medium layer 62 and the electrically conductive main layer 64. In light of this, the electrically conductive layer 80 likewise provides electric conduction to attain the same effect.

It is to be noted that the insulated layer can alternatively be formed as aluminum nitride by nitrogenizing the metallic substrate or as nitrogen oxide of aluminum by oxidizing and nitrogenizing the metallic substrate at the same time to have excellent thermal conductivity. In addition, if a specific circuit layout is intended to be formed on the substrate, the first medium layer and the electrically conductive layer can be treated by mask erosion to form a predetermined design; alternatively, only the electrically conductive layer can be treated by milling or mask erosion to form a predetermined design. Furthermore, each of the first medium layer and the electrically conductive layer can alternatively be multiple-layered.

To sum it up, the aforementioned preferred embodiments demonstrate that the present invention provides the highly thermally conductive substrate employing the first medium layer for the buffer interface to overcome the overgreat difference of the physical property between the insulated and electrically conductive layers to further increase the adherence therebetween. Compared with the prior art, the present invention intensifies the structure between the first medium layer and the electrically conductive layer to enhance the structural intensity. The present invention also has better thermal conductivity.

Although the present invention has been described with respect to specific preferred embodiments thereof, it is no way limited to the details of the illustrated structures but changes and modifications may be made within the scope of the appended claims.

What is claimed is:

1. A highly thermally conductive circuit substrate comprising:
a metallic substrate;
an insulated layer formed on a surface of said metallic substrate;
at least one first medium layer formed on a surface of said insulated layer; and
an electrically conductive layer formed on a surface of said first medium layer.

2. The highly thermally conductive circuit substrate as defined in claim 1, wherein said metallic substrate is made of a material selected from a group consisting of aluminum, magnesium, titanium, and an alloy of at least two of them.

3. The highly thermally conductive circuit substrate as defined in claim 1, wherein said insulated layer is formed by means of electrochemical colloid oxidation (ECCO) anodizing that the working solution is oxalic acid, the predetermined working voltage is 260-400 volts, and the predetermined working current is 2-5 A/dm².

4. The highly thermally conductive circuit substrate as defined in claim 1, wherein said insulated layer is made of a compound of the surface of said metallic substrate.

5. The highly thermally conductive circuit substrate as defined in claim 1, wherein said first medium layer is made of magnesium, aluminum, titanium, vanadium, chromium, nickel, zirconium, molybdenum, tungsten, or a compound of at least two of them.

6. The highly thermally conductive circuit substrate as defined in claim 5, wherein said first medium layer is made of titanium oxide.

7. The highly thermally conductive circuit substrate as defined in claim 1, wherein said electrically conductive layer is made of aluminum, cobalt, nickel, copper, zinc, argentums, tin, platinum, or gold.

8. The highly thermally conductive circuit substrate as defined in claim 1, wherein said electrically conductive layer is at least formed of an electrically conductive medium layer and an electrically conductive main layer, said electrically conductive main layer being formed on a surface of said electrically conductive medium layer.

9. The highly thermally conductive circuit substrate as defined in claim 8, wherein said electrically conductive medium layer has a thickness smaller than 1 μm.

10. The highly thermally conductive circuit substrate as defined in claim 8, wherein said electrically conductive main layer has a thickness larger than 13 μm.

11. The highly thermally conductive circuit substrate as defined in claim 1, wherein said insulated layer is made of nitride of a metal that said metallic substrate is made.

12. The highly thermally conductive circuit substrate as defined in claim 1, wherein said insulated layer is made of nitrogen oxide of a metal that said metallic substrate is made.

13. The highly thermally conductive circuit substrate as defined in claim 1, wherein said insulated layer is made of oxide of a metal that said metallic substrate is made.

14. The highly thermally conductive circuit substrate as defined in claim 1, wherein said electrically conductive layer and said first medium layer are formed in a predetermined design.

15. The highly thermally conductive circuit substrate as defined in claim 1, wherein said electrically conductive layer is formed in a predetermined design.
